(19) United States
(12) Patent Application Publication
(10) Pub. No.: US 2008/0241384 A1
(43) Pub. Date: Oct. 2, 2008

(54) LATERAL FLOW DEPOSITION APPARATUS AND METHOD OF DEPOSITING FILM BY USING THE APPARATUS

(75) Inventors: Sang Jin Jeong, Daejeon-si (KR); Dae Youn Kim, Daejeon-si (KR); Jung Soo Kim, Cheonan-si (KR); Hyung Sang Park, Seoul-si (KR); Chun Soo Lee, Daejeon-si (KR)

Correspondence Address: KNOBBE MARTENS OLSON & BEAR LLP, 2040 MAIN STREET, FOURTEENTH FLOOR, IRVINE, CA, 92614, US

(73) Assignee: ASM Genitech Korea Ltd., Cheonan-si (KR)

(21) Appl. No.: 12/058,364

(22) Filed: Mar. 28, 2008

(30) Foreign Application Priority Data
Apr. 2, 2007 (KR) 10-2007-0032422

(51) Int. Cl. C23C 16/00

(52) U.S. Cl. 427/255.29; 118/730; 118/719

(57) ABSTRACT

A deposition apparatus and deposition method for forming a film on a substrate are disclosed. A film is deposited on a substrate by exposing the substrate to different flow directions of reactant gases. In one embodiment, the substrate is rotated in the reaction chamber after a film having an intermediate thickness is formed on the substrate. In other embodiments, the substrate is transferred from one reaction chamber to another after a film having an intermediate thickness is formed on the substrate. Accordingly, a film having a uniform thickness is deposited, averaging out depletion effect.

### CROSS-REFERENCE TO RELATED APPLICATIONS

This application claims priority to and the benefit of Korean Patent Application No. 10-2007-0032422 filed in the Korean Intellectual Property Office on Apr. 2, 2007, the entire contents of which are incorporated herein by reference.

### BACKGROUND OF THE INVENTION

1. Field of the Invention

The present invention relates to a lateral flow deposition apparatus and a method of depositing a film by using the apparatus.

2. Description of the Related Art

In manufacturing semiconductor devices, efforts for improving apparatus and processes to form a high quality thin film on a substrate are continuing. In atomic layer deposition (ALD) methods, separate pulses of at least two reactants are sequentially introduced to a substrate and a surface reaction between the reactants and the surface of the substrate occurs to form a monolayer on the surface of the substrate. The reactants are sequentially introduced until a desired thickness of the deposited material is formed. In pure ALD methods, the reactants are pulsed separately within a temperature range above the reactants' condensation temperatures and below their thermal decomposition temperatures. The thin film is formed by surface reaction, and thus a thin film having a uniform thickness may be formed on the entire surface of the substrate regardless of surface roughness of the substrate. In addition, impurities in the thin film may be reduced to form a high quality thin film.

In a simple example of an atomic layer deposition method, gas pulses consisting of four sequential steps including first reactant gas supply, inert purge gas supply, second reactant gas supply, and inert purge gas supply are repeated. A pulse of a purge gas between the pulses of the different reactants reduces the gas phase reactions of the reactants due to excess amounts of the reactants remaining in the chamber such that a thin film is formed by a surface reaction occurring on the surface of the substrate. Here, a portion of the reactant gases may be activated by plasma. A plasma atomic layer deposition method of generating discontinuous plasma in line with the pulses of the reactant gases in a reaction chamber is disclosed in Korean Patent No. 273473 and U.S. Pat. No. 6,645,574.

Among the atomic layer deposition apparatuses used in the ALD methods, a lateral flow ALD reactor, in which gases flow laterally over and parallel to the surface of a substrate, has been proposed. In the lateral flow ALD reaction chamber, flow of the gases is rapid and simple and thereby reactant gases can be switched and purged rapidly to reduce time required for supplying process gases sequentially. An example of lateral flow reactor suitable for time-divided gas supplying ALD method and a method of depositing a thin film using the lateral flow reactor have been disclosed in Korean Patent No. 624030 and U.S. Pat. No. 6,539,891. In addition, an improved example of the lateral flow reactor suitable for time-divided gas supplying ALD method and a method of depositing a thin film using the lateral flow reactor have been disclosed in Korean Patent Application No. 2005-0038606 and U.S. patent application Ser. No. 11/429,533 published as U.S. Publication No. 2006-0249077 A1 on Nov. 9, 2006. Here, the plasma atomic layer deposition method of generating discontinuous plasma may be applied to the lateral flow reactor by supplying RF power to the electrode in line with the pulses of the reactants gases.

Other examples of lateral flow ALD reactors have been disclosed in U.S. Pat. No. 5,711,811 and U.S. Pat. No. 6,562,140. In these examples, the reactors have a constant gap between a portion supporting a substrate and another portion facing a surface of the substrate such that gas flowing over the substrate may be constant and maintained substantially laminar.

The above information disclosed in this Background section is only for enhancement of understanding of the background of the invention and therefore it may contain information that does not form the prior art that is already known in this country to a person of ordinary skill in the art.

### SUMMARY OF THE INVENTION

One embodiment is a method of depositing a film over a substrate. The method includes in sequence: flowing one or more reactant gases horizontally over a substrate in a first direction relative to the substrate until a first film having a first thickness is formed over the substrate; stopping flowing the reactant gases over the substrate; and flowing the reactant gases horizontally over the substrate in a second direction relative to the substrate until a second film having a second thickness is formed over the first film. The first thickness is thinner than a target thickness. The second thickness is thinner than the target thickness. The second direction is different from the first direction.

Another embodiment is a method of depositing a film over a substrate. The method includes in sequence: flowing one or more reactant gases horizontally over a substrate in a first direction in a first reactor to form a first film over the substrate; transferring the substrate from the first reactor to a second reactor; and flowing the same reactant gases horizontally over the substrate in a second direction in the second reactor to form a second film over the first film. The second direction is different from the first direction relative to the substrate. The first and second films are formed of the same material.

Yet another embodiment is an apparatus for depositing a thin film over a substrate. The apparatus includes: a reaction chamber configured to define an enclosed reaction space in which deposition is performed on a substrate. The reaction space is configured to provide a laminar gas flow in a direction over the substrate. The apparatus further includes a driver configured to rotate the substrate while deposition is not performed on the substrate such that the orientation of the substrate relative to the direction of the laminar gas flow is different from the orientation of the substrate before being rotated.

Yet another embodiment is an apparatus for depositing a thin film over a substrate. The apparatus includes a plurality of reaction chambers. Each of the reaction chambers is configured to define an enclosed reaction space in which deposition is performed on a substrate. The reaction space is configured to provide a laminar gas flow in a direction over the substrate. The reaction chambers are configured to provide the same reactant gases as one another into the reaction spaces. The apparatus also includes a transfer device configured to transfer a substrate from one of the reaction chambers to another of the reaction chambers. The orientation of the substrate relative to the direction of the laminar gas flow in the one reaction chamber is different from the orientation of the substrate relative to the direction of the laminar gas flow in the other reaction chamber.

### BRIEF DESCRIPTION OF THE DRAWINGS

FIG. 1A and FIG. 1B are schematic plan views of a substrate illustrating a method of lateral flow deposition according to one embodiment.

FIG. 2A and FIG. 2B are cross-sectional views of a lateral flow deposition apparatus according to one embodiment.

FIG. 3 is a cross-sectional view of a lateral flow deposition apparatus according to another embodiment.

FIG. 4A is a perspective view of a lateral flow deposition apparatus according to yet another embodiment.

FIG. 4B is a top plan view of the lateral flow deposition apparatus of FIG. 4A.

FIG. 5 is a schematic top plan view of a lateral flow deposition chamber having four reaction chambers according to yet another embodiment.

FIG. 6 is a schematic plan view of a lateral flow deposition apparatus according to yet another embodiment.

FIG. 7 is a schematic plan view of a deposition apparatus including four reaction chambers and a robot arm programmed to rotate the substrate between transfers according to yet another embodiment.

### DETAILED DESCRIPTION OF THE PREFERRED EMBODIMENT

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Films deposited in the lateral flow deposition reaction chambers described above may have a non-uniform thickness. In a lateral flow deposition apparatus, reactants typically flow from an upstream region to a downstream region in a chamber. Because a portion of the reactants is consumed for reaction with the surface of a substrate in the chamber while flowing from the upstream region to the downstream region, reactants are in a higher concentration in the upstream region than in the downstream region. Thus, a portion of the resulting film that is formed in the downstream region may be thinner than another portion of the film that is formed in the upstream region. Such effect is generally referred to as depletion effect. Furthermore, to the extent an ALD reaction exhibits non-ideal ALD behavior, such as CVD-type reactions between residual reactants or by-product and a subsequent pulse tend also to occur non-uniformly along the flow path.

In one embodiment, a film having a desired thickness is formed on a substrate through multiple steps. A film having a first intermediate thickness thinner than the desired thickness is formed on the substrate during one of the steps, which may be CVD or include multiple ALD cycles. Then, the pre-formed film is grown to the desired thickness during one or more additional steps, each of which may be CVD or include multiple ALD cycles for depositing the same material. In these multiple steps, horizontal gas flows are provided over the substrate in different directions. These steps can be repeated until the film having the desired thickness is formed on the substrate. Because the substrate is exposed to gas flows in different directions during the multiple steps, depletion effects and/or other flow-axis non-uniformities on the substrate are averaged out. Thus, non-uniformity in thickness that would otherwise occur can be reduced or eliminated.

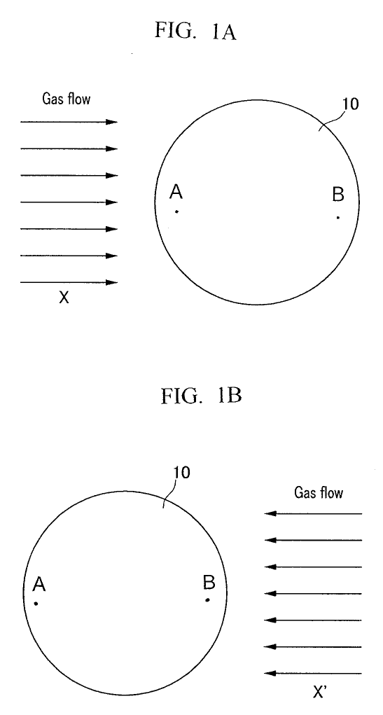

Now, a deposition method according to one embodiment will be described with reference to FIGS. 1A and 1B. As shown in FIG. 1A, a film is grown to have a selected intermediate thickness, for example, up to about 50% of a desired final thickness, by reactant gases flowing over a substrate 10 in a first direction X. In FIG. 1A, a first portion A of the substrate 10 is located at an upstream position, and a second portion B of the substrate 10 is located at a downstream position. Then, the film is further grown to the desired final film thickness by reactant gases flowing over the substrate 10 in a second direction X′, as shown in FIG. 1B. In the illustrated embodiment, the second direction X′ is opposite from the first direction X, and thus, the first portion A is now located at a downstream position, and a second portion B is now located at an upstream position.

FIGS. 1A and 1B should be understood to illustrate relative directions. The same result can be achieved by rotating the substrate 180°, rather than changing the direction of the flow over a stationary substrate. Similarly, in another embodiment, a film is grown on a substrate to have a selected intermediate thickness in a first reactor, and then the substrate is transferred to a second reactor. In the second reactor, gases flow over the substrate 10 in the second direction X′ to form the other 50% of the desired film.

Furthermore, while only a single switch in relative flow direction by 180° is described above, and for improving thickness uniformities better efficiently, in some circumstances, it may be advisable to increase the number of switches. For example, 25% of the film could be deposited in each of four steps with 3 rotations of 180° between steps. Similarly, 10% of the film could be deposited in each of 10 steps with 180° rotation in the relation of flow/substrate orientation between each step. Compositional non-uniformities (stoichiometry) can be better averaged out with greater number of steps, at the expense of efficiency.

In another embodiment, the substrate 10 may be rotated by about 180° in a reactor with a lateral gas flow in the first direction X after a film is grown to have a selected intermediate thickness. By the rotation of the substrate 10, the substrate 10 is now exposed to the same lateral gas flow, but in the opposite relative direction.

Although not shown here, instead of dividing the desired final thickness of the film into two (i.e., forming two stacked films, each having about 50% of the final thickness), the desired final thickness of the film may be divided into three. In other words, a film having a thickness of about one-third of the desired thickness may be formed on the substrate, and then the substrate may be rotated by about 120°. Then, a film having a thickness of about one-third of the desired thickness may again be formed on the substrate. Next, the substrate may be rotated by about 120° again, and a final one-third thickness of the film may be formed on the substrate.

In other embodiments, the desired final thickness of the film may be divided into n, and about 1/n of the desired thickness of the film may be formed (e.g., by CVD for a duration or multiple ALD cycles) in a reactor in which gases flow in a constant direction, and the substrate may be rotated by about 360°/n each time. The above process may be repeated n times to form the film having the desired thickness. In one embodiment, n may be a natural number of 2 to 8, and particularly, n may be 2, 3, or 4.

In other embodiments, the desired thickness of the film may be divided into n, and about 1/n of the desired thickness of the film may be formed in a reactor in which gases flow in a constant direction. Then, the substrate may be transferred into another reactor in which gases flow in a direction rotated by about 360°/n from the gas flow direction of the previous reactor. The above process may be repeated n times to form the film having the desired thickness. In one embodiment, n is a natural number of 2 to 8, and particularly n may be 2, 3, or 4.

In the deposition methods described above, the deposition process of forming about 1/n of the desired thickness of the film in a reactor in which gases flow in a constant direction and rotating the substrate by about 360°/n may be repeated n times to form the film having the desired thickness. Alternatively, the deposition process of forming about 1/n of the desired thickness of the film in a reactor in which gases flow in a constant direction and transferring the substrate into another reactor in which gases flow in a direction rotated by about 360°/n from the gas flow direction in the previous reactor may be repeated n times to form the film having the desired thickness. Accordingly, a film having a substantially uniform thickness may be deposited in a lateral flow deposition apparatus.

If n is excessively large, the time required for rotating or transferring the substrate is excessively long such that productivity of the deposition chamber may be decreased. However, in the deposition method described above, n is a natural number of 2 to 8, and preferably n is one of 2, 3, and 4, such that adverse effects on the productivity of the deposition chamber may be avoided. A skilled artisan will, however, appreciate that the number n can vary widely, depending on the deposition thickness and condition.

In the embodiments described above, the substrate and/or flow direction is rotated about 360° during the entire deposition process. In certain embodiments, a substrate and/or flow direction may be rotated more than 360° during the entire deposition process. For example, a substrate and/or flow direction may be rotated about 360°×m, where m is equal to or greater than 2, depending on the desired film thickness. Desirably, m is an integer less than or equal to 4 in order to minimize time lost during adjustment of relative flow direction. However, for some types of non-uniformity (e.g., compositional non-uniformity), greater numbers of rotations m and/or greater numbers of rotational increments n will be beneficial. However, if m is greater than 4, using a non-integer or fractional m will not have too great an adverse effect on uniformity. A skilled artisan will appreciate that the substrate and/or flow direction can be rotated any suitable angle, depending on the desired film thickness and/or deposition chamber configuration.

### Deposition Apparatus Having a Single Reactor

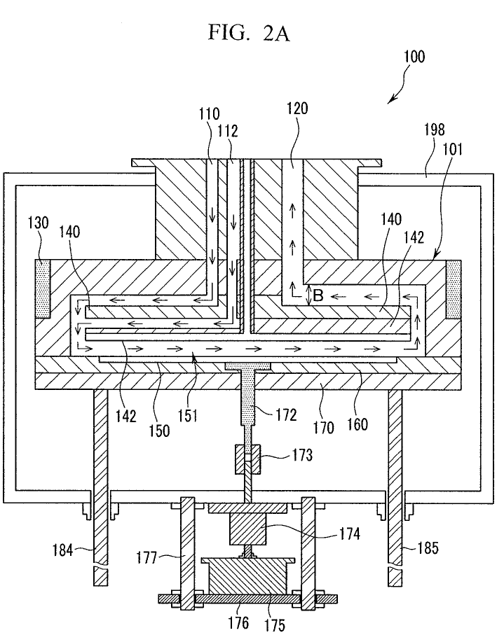

Now, a reaction chamber of a lateral flow deposition apparatus according to one embodiment will be described in detail with reference to FIG. 2A and FIG. 2B. FIG. 2A and FIG. 2B are cross-sectional views of a lateral flow deposition apparatus according to one embodiment. FIG. 2A represents a lateral flow deposition apparatus during a depositing process and FIG. 2B represents a lateral flow deposition apparatus during an interval between depositing processes.

Referring to FIG. 2A and FIG. 2B, a lateral flow deposition apparatus 100 according to one embodiment includes an outer wall 198, a substrate holder 160, and a reactor cover 101. The reactor cover 101 and the substrate holder 160 together form a reaction chamber which defines a reaction space 151 in which a substrate 150 is processed. The deposition apparatus 100 also includes separate gas inlets 110 and 112 connected to the reactor cover 101 and configured to supply process gases into the reaction chamber, a gas outlet 120 connected to the reactor cover 101 and configured to exhaust gas from the reaction chamber, a substrate heater 170 configured to heat the substrate holder 160, a substrate holder vertical movement mechanism configured to vertically move the substrate holder 160 and the substrate heater 170, and a substrate rotary movement mechanism configured to rotate the substrate 150 relative to the direction of flow. One of the gas inlets 110 and 112 may be omitted.

The reactor cover 101 may also include a cover heater 130 on outer surfaces of the reactor cover 101 to heat the reactor cover 101. The lateral flow deposition apparatus 100 may also include gas flow control guide structures 140 and 142 in the reaction chamber. The gas flow control guide structures 140 and 142 are configured to generate a lateral gas flow over the substrate 150. The lateral gas flow may be a substantially laminar flow.

The substrate vertical movement mechanism may include three or more supporting rods 184 and 185 connected to the substrate holder 160, and a driving device (not shown), such as a pneumatic cylinder. The driving device is configured to move the supporting rods 184 and 185 in a vertical direction.

The substrate rotary movement mechanism may include a supporting pin 172 holding the substrate 150, a supporting pin holder 173 in which the supporting pin 172 is inserted, and a supporting pin rotary movement mechanism connected to the supporting pin holder 173. The supporting pin rotary movement mechanism may include an electric motor 175 such as a step motor, a feed-through 174 for rotation connected to the electric motor 175, a fixing plate 176 equipped with the electric motor 175, and a fixing rod 177 connected to the fixing plate 176. The lateral flow deposition apparatus 100 may further include a supporting pin vertical movement mechanism (not shown) configured to move the supporting pin 172 in a vertical direction. The supporting pin vertical movement mechanism may include an electric motor and a pneumatic cylinder. Alternatively, the substrate can be lifted from the substrate holder 160 by interaction of the supporting pin 172 with the supporting pin holder 173 during downward movement of the substrate holder 160.

A part of the lower portion of the supporting pin 172 inserted into the supporting pin holder 173 is chamfered such that the lower portion below the supporting pin 172 does not have a complete cylindrical shape. Accordingly, a rotary motion of the supporting pin rotary movement mechanism is effectively transferred to the supporting pin 172 through the supporting pin holder 173. The supporting pin 172 may be moved to a vertical direction along with the supporting pin holder 173.

The supporting pin rotary movement mechanism may include a device that is able to rotate by a predetermined angle using air pressure as well as electric means such as the electric motor 175.

Now, a deposition method according to one embodiment using the lateral flow deposition apparatus shown in FIG. 2A and FIG. 2B will be described in detail. First, a substrate 150 is loaded onto the substrate holder 160, in the position of FIG. 2B. Then, the substrate holder 160 is moved upward to contact the reactor cover 101 to define a reaction space 151 in the position of FIG. 2A. A film having a thickness of up to about 50% of a desired final thickness is formed by sequentially supplying reactant gases, e.g., by CVD or in a plurality of ALD cycles alternating two or more reactants, into the reaction space 151, as shown in FIG. 2A.

Next, the supply of the reactant gases is stopped and the substrate holder 160 is moved downward using the substrate holder vertical movement mechanism as shown in FIG. 2B. Here, the supporting pin 172 interacts with the supporting pin holder 173 such that it is not moved downward such that the substrate 150 is detached from the substrate holder 160. After the substrate 150 is detached from the substrate holder 160, the electric motor 175 is rotated. The rotary motion of the motor 175 is transferred to the supporting pin 172 and the substrate 150 through the feed-through 174 such that the supporting pin 172 and the substrate 150 are rotated by about 180°. Then, the substrate holder 160 is moved upward using the substrate holder vertical movement mechanism such that the substrate holder 160 contacts the reactor cover 101 to define the reaction space 151, as shown in FIG. 2A. The preformed film is further grown, e.g., by CVD or another plurality of ALD cycles to deposit the same material to have the desired final thickness by sequentially supplying reactant gases into the reaction space 151.

After the film having the desired thickness is formed, supply of the reactant gases is stopped and the substrate holder 160 is moved downward. Here, the supporting pin 172 interacts with the supporting pin holder 173 such that it is not moved downward and the substrate 150 is detached from the substrate holder 160. Then, the substrate 150 is unloaded from the reactor using transfer equipment such as a robot arm (not shown), and another substrate may be loaded into the reactor.

If a robot arm that may not be moved in a vertical direction is used, the robot arm may be disposed at a position in a reactor suitable for transferring the substrate, and then the supporting pin 172, the supporting pin holder 173 and the supporting pin rotary movement mechanism may be moved downward by using the supporting pin vertical movement mechanism. The supporting pin 172 is moved downward and the robot arm supports the substrate 150 when it is detached from the supporting pin 172. The robot arm is then moved outside of the reactor such that the substrate 150 is unloaded from the reactor and another substrate is loaded into the same position in which the supporting pin 172 supports the substrate 150. Next, the supporting pin 172, the supporting pin holder 173, and the supporting pin rotary movement mechanism are moved upward by using the supporting pin vertical movement mechanism such that the supporting pin 172 supports the new substrate and the robot arm is moved outside of the reactor.

Meanwhile, if a robot arm movable in a vertical direction is used, the substrate may be transferred without vertically moving the supporting pin 172. Accordingly, the supporting pin vertical movement mechanism may be omitted. The supporting pin vertical movement mechanism may include an electric motor and a pneumatic cylinder.

In this case, the substrate holder 160 is moved upward by using the substrate holder vertical movement mechanism such that the substrate holder 160 contacts the reactor cover 101 and the film having the desired thickness is deposited on the new substrate using the same method as described above.

Likewise, in one embodiment where the desired film is deposited by dividing in n times, a film having a thickness of about 1/n of the desired thickness is formed on the substrate 150 in the reactor with gases flowing in a constant direction. After that, the supply of the reactant gases is stopped and the substrate 150 and the supporting pin 172 may be rotated by about 360°/n. The above process may be repeated n times to form a film having the desired thickness.

As described above, the supporting pin rotary movement mechanism rotates by a constant angle such as about 180°, about 120°, or about 90°. The supporting pin rotary movement mechanism may include a device that rotates by a constant pre-selected angle by using air pressure as well as an electric means such as the step motor.

### Deposition Apparatus Having Multiple Reactors

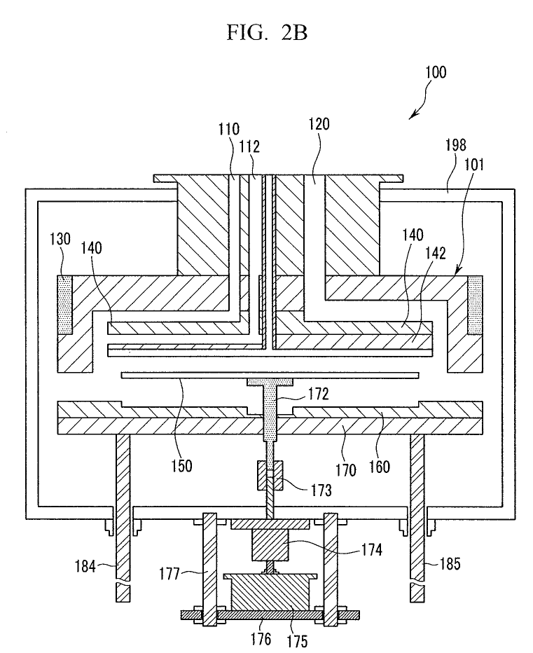

Now, a lateral flow deposition apparatus according to another embodiment will be described in detail with reference to FIG. 3. FIG. 3 is a cross-sectional view of the lateral flow deposition apparatus.

The illustrated lateral flow deposition apparatus includes a plurality of lateral flow reaction chambers, and a substrate moving mechanism for moving a plurality of substrates. The reaction chambers are arranged to form a path. The substrate moving mechanism serves to move the substrate from one reaction to another along the path during a deposition circuit. The substrates are processed in at least two of the reaction chambers during the deposition circuit, i.e., a film having the desired thickness is formed on a substrate by deposition steps performed in two or more of the reaction chambers. The reaction chambers and the substrate moving mechanism are together configured to provide different relative orientations between the substrates and the gas flow directions in different reaction chambers.

In the illustrated embodiment, the gas flow directions in the reaction chambers are fixed and substantially parallel to one another, but the substrates are rotated less than 360° (relative to the common gas flow direction) by the substrate moving mechanism when they are transferred from one reaction chamber to another. As a result, the gas flow directions relative to the substrates are different in different reaction chambers.

The deposition apparatus of FIG. 3 includes a plurality of reaction chambers. The deposition apparatus includes reactor covers 301a and 301b, substrate holders 360a and 360b, and substrate supporting pins 361a and 361b inserted into the substrate holders 360a and 360b. The reactor covers 301a and 301b and the substrate holders 360a and 360b define a plurality of reaction chambers or reaction spaces in which substrates are processed.

Each of the reactor covers 301a and 301b includes gas inlets 310 and 312 configured to supply process gases into the reaction chamber, and a gas outlet 320 configured to exhaust gas from the reaction chamber. One of the gas inlets 310 and 312 may be omitted, particularly for CVD, but for ALD a separate inlet for each reactant is preferred. Although not shown, each of the inlets 310 may be connected to each of reactant gas supply tubes symmetrically diverging from one reactant source supply apparatus, and similarly for 312. Thus, each reaction chamber is configured to vapor deposit the same material. In addition, exhaust tubes connected to the each gas outlet 320 may be converging symmetrically to one exhaust tube connected to an external exhaust vacuum pump (not shown).

Each of the reaction chambers also includes gas flow control guide structures 340 and 342 configured to maintain a substantially laminar gas flow over the substrates. Each of the gas flow control guide structures 340 and 342 may be configured to provide a gas flow in a fixed direction. In the illustrated embodiment, the gas flow control guide structures 340 and 342 are configured to provide gas flows in substantially the same direction as each other in the reaction chambers.

The deposition apparatus also includes a reactor base 372 configured to support both of the substrate holders 360a and 360b. The substrate holders 360a and 360b may be detachably fixed to the reactor base 372 while not being rotatable relative to the reactor base 372 when the chambers are closed for deposition. The deposition apparatus further includes supporting pins 361a and 361b configured to hold the substrates while moving the substrate holders 360a and 360b downward, and supporting pin holders 365a and 365b that are fixed relative to the outer wall 398, configured to support the supporting pins 361a and 362b when the chambers are opened.

In addition, the deposition apparatus includes a substrate transfer mechanism. The substrate transfer mechanism serves to horizontally rotate the substrate holders 360a and 360b during a deposition process. The substrate transfer mechanism may includes a plurality of driving guide posts 382 connected to an outer wall 398, a lower fixing plate 381 to which the driving guide posts 382 are connected, a driving plate 383 connected to the driving guide posts 382 through bearings 386, connecting supporters 373 into which projecting portions of the reactor base 372 are inserted, a feed-through 374 for rotation, an electric motor 375, a pneumatic cylinder for vertical motion 384, and a bellows 385 for allowing vertical motion while sealing the bottom of the reactor.

The reactor base 372 may be moved vertically and may be rotated horizontally by the substrate transfer mechanism. First, vertical movement of the substrate transfer mechanism is described. The pneumatic cylinder 384 for vertical motion causes the driving plate 383 (to which the electric motor 375 and the feed-through 374 for rotation are connected) to move vertically. The vertical motion of the driving plate 383 is transferred to the reactor base 372 supporting the substrate holders 360a and 360b through the rotary posts 376 of the electric motor 375 and the connecting supporters 373 such that the substrate holders 360a and 360b may be moved vertically. Here, the bellows 385 allows proper displacement while driving vertically.

The substrate holders 360a and 360b and the reactor base 372 are moved downward such that the substrates are detached from the reaction chambers, but only to a vertical level that the substrate supporting pins 361a and 361b do not contact the supporting pin holders 365a and 365b. Then, the electric motor 375 is rotated. The rotary motion of the electric motor 375 is transferred to the reactor base 372 through the feed-through 374 for rotation and the connecting supporters 373 such that the reactor base 372 is rotated. Accordingly, the substrate holders 360a and 360b are rotated such that the substrates on the substrate holders 360a and 360b are transferred from one reaction chamber to another reaction chamber.

In the illustrated embodiment, because the substrate holders 360a, 360b are kept in the same position relative to the reactor base 372, the substrates are rotated by 180° when they are transferred from one reaction chamber to another. During a deposition process, a first portion of a desired film thickness is deposited on each substrate in each of the reaction chambers, and then a second portion of the desired film thickness (typically the same material) is deposited in the other of the reaction chambers, as will be better understood from description below.

In the illustrated embodiment, the deposition apparatus includes two reaction chambers. A skilled artisan will, however, appreciate that the deposition apparatus can include more than two reaction chambers. In one embodiment, a deposition apparatus includes two to eight reaction chambers, and particularly two to four reaction chambers.

Now, a deposition method according to one embodiment, using the lateral flow deposition apparatus of FIG. 3 will be described in detail. First, substrates are loaded onto the substrate holders 360a and 360b, while supported by the supporting pin holders 361a, 361b. The reactor base 372 is then moved upward such that the bottom of the reactor cover 301a contacts the substrate holder 360a and the bottom of the reactor cover 301b contacts the substrate holder 360b respectively, thereby forming enclosed reaction spaces. Films having an intermediate thickness are formed on the substrates in the reaction chambers by sequentially supplying reactant gases into the reaction chambers. In one example, the intermediate thickness may be up to about 50% of a desired final thickness of the resulting film.

Next, the supply of the reactant gases is stopped, and the substrate holders 360a and 360b are moved downward by moving the reactor base 372 downward to the position shown in FIG. 3. Then, the reactor base 372 is rotated by about 180° such that the substrate holders 360a and 360b are positioned under different reactor covers. For example, the substrates, which have been under the reactor covers 301a and 301b, are moved to under the reactor covers 301b and 301a, respectively, by the rotation of the reactor base 372, at the same time changing the substrate orientations relative to the outer walls 398 and the gas flow direction.

Next, the substrate holders 360a and 360b are moved upward such that the reactor cover 301a contacts the substrate holder 360b and the reactor cover 301b contacts the substrate holder 360a respectively, thereby forming enclosed reaction spaces. Then, the preformed films on the substrates are grown to have the desired final thickness, e.g., another film having a thickness of about 50% of the desired final thickness is formed on each of the substrates.

After the films having the desired thickness have been formed, supply of the reactant gases is stopped and the substrate holders 360a and 360b are moved downward. Next, the substrates are unloaded from the reaction chambers, and other new substrates may be loaded into the reaction chambers. The above processes can be repeated.

In a lateral flow deposition apparatus in which reactants flow from an upstream region to a downstream region, a resulting film may have non-uniformity (e.g., in thickness) between portions thereof in the upstream and downstream regions due to the fact that reactants are in a higher concentration in the upstream region than in the downstream region. In the embodiment described above, however, films are deposited on substrates while the substrates are exposed to reactant gases flowing different directions (about 180° in the illustrated embodiment) in different reaction chambers. In the example of FIG. 3, the reactant gases flow in the same direction in both chambers, while the substrates are rotated by 180° relative to that flow direction by rotation of the reactor base 372. Accordingly, uniformity of a film deposited in the lateral flow deposition apparatus may be improved while two or more substrates may be processed simultaneously.

In other embodiments, a lateral flow deposition apparatus may include three or more substrate holders supporting three or more substrates. The three or more substrates are transferred from a reaction chamber to another such that they are exposed to different gas flows (relative to substrate orientation) in different reaction chambers. In one embodiment, the deposition apparatus includes two to eight reaction chambers, and preferably two to four reaction chambers. Accordingly, the rotation angle of the substrate holders may be changed by the number of reaction chambers such that the rotation angle of the substrate holders may be about 180°, about 120°, and about 90° when the number of the reaction chambers is two, three, and four, respectively.

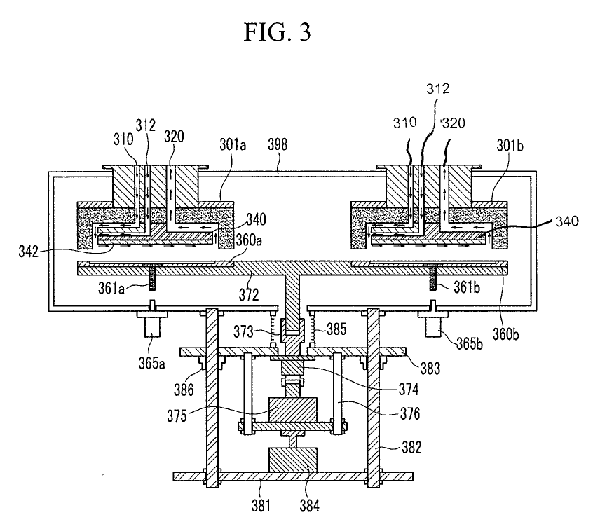

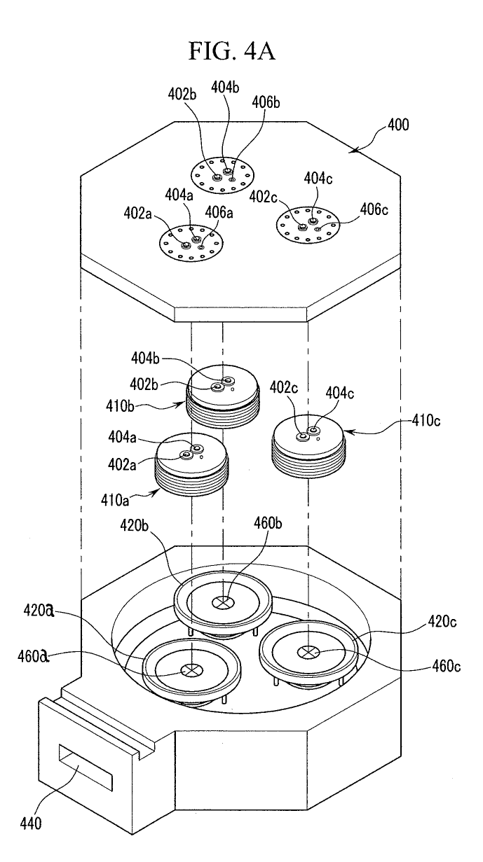

Now, a lateral flow deposition apparatus according to another embodiment will be described in detail with reference to FIG. 4A and FIG. 4B. FIG. 4A is a perspective view of the lateral flow deposition apparatus, and FIG. 4B is a top plan view of the lateral flow deposition apparatus of FIG. 4A.

The lateral flow deposition apparatus according to this embodiment includes a plurality of lateral flow reaction chambers, and a substrate transfer mechanism for transferring a plurality of substrates loaded in the reaction chambers among the reaction chambers. The gas flow directions in the reaction chambers are fixed and substantially parallel to one another, but the substrates are rotated relative to the gas flow direction less than 360° by the substrate moving mechanism when they are transferred from one reaction chamber to another. As a result, the gas flow directions relative to the substrates are different in different reaction chambers.

Referring to FIG. 4A, the chamber 400 includes three reaction chambers. Each of the reaction chambers respectively includes a reactor cover 410a, 410b, 410c, a substrate holder 420a, 420b, and 420c, and a supporting pin 460a, 460b, and 460c inserted into the substrate holder 420a, 420b, and 420c. Each of the reactor covers 410a, 410b, and 410c defines a reaction space along with one of the substrate holders 420a, 420b, and 420c. Each of the reactor covers 410a, 410b, and 410c includes at least one gas inlet 402a, 402b, and 402c and a gas outlet 404a, 404b, and 404c, and is fixed to the cover of the chamber 400 by a fastening mechanism 406a-406c. The reactor cover also includes a gas flow control guide structure (not shown) configured to provide a substantially laminar gas flow over substrates.

Even though the gas inlets 402a, 402b, and 402c and the gas outlets 404a, 404b, and 404c are provided in the reactor cover, and the gas inlets 402a, 402b, and 402c and the gas outlets 404a, 404b, and 404c are connected respectively to a separate gas supply device (not shown) and an exhaust device (not shown), in FIG. 4A, a single gas supply device may be provided in the reactor cover. The gas inlets 402a, 402b, and 402c may be connected to each of gas supply tubes symmetrically diverged from the one gas supply device toward the reaction chambers, respectively. In addition, each of gas outlets 404a, 404b, and 404c may be connected to an external exhaust vacuum pump (not shown) in the manner that exhaust tubes connected to each of gas outlets 404a, 404b, and 404c may be symmetrically converged to one exhaust tube connected to an external exhaust vacuum pump (not shown). The substrate holders 420a, 420b, and 420c may include substrate heaters (not shown) configured to heat the substrate holders and the substrates.

The substrate holders 420a, 420b, and 420c may move vertically such that the substrate holders 420a, 420b, and 420c define reaction spaces by contacting to the reactor covers 410a, 410b, and 410c.

The reactor 400 includes supporting pins 460a, 460b, and 460c configured to support the substrates while moving downward the substrate holders 420a, 420b, and 420c. Even though one supporting pin having a round shape is shown to be provided in each reaction chamber in FIG. 4A, the supporting pin may have a different shape and may be arranged differently. For example, three supporting pins that are in point contact with each substrate at positions away from the center of each substrate may be used for the supporting pin.

A substrate entrance 440 for a loading and unloading path of the substrates is provided at one side of the chamber exterior wall. The substrate may be loaded to or unloaded from each reaction chamber through the substrate entrance 440.

Now, the substrate transfer mechanism in the lateral flow apparatus according to the present embodiment will be described with reference to FIG. 4B. The illustrated substrate transfer mechanism includes a plurality of arms 490a, 490b, and 490c that are configured to load or unload the substrates, and an arm axis 492 connecting to the plurality of arms 490a, 490b, and 490c.

The arm axis 492 may be connected to an arm driving mechanism that is configured to drive the arm axis 492 to move vertically and rotate horizontally. The arms 490a, 490b, and 490c may support the substrates, while not preventing the supporting pins 460a, 460b, and 460c from moving vertically.

In FIG. 4B, the arms 490a, 490b, and 490c have a hook shape. However, the arms may have other shapes that may support the substrates while not preventing vertical movement of supporting pins.

The arms 490a, 490b, and 490c sequentially receive three substrates entering through the substrate entrance 440 and then load the substrates on the supporting pins 460a, 460b, and 460c, respectively, by lowering the arms 490a, 490b, and 490c and/or raising the supporting pins 460a, 460b, 460c. After the substrates are loaded on the supporting pins 460a, 460b, and 460c, the arms 490a, 490b, and 490c are positioned as shown in FIG. 4B such that the arms 490a, 490b, and 490c may not prevent the substrate holders 420a, 420b, and 420c from moving vertically.

Even though three reaction chambers are shown in FIG. 4A and FIG. 4B, the deposition apparatus may include two to eight reaction chambers, and preferably includes two to four reaction chambers.

Now, a deposition method according to an embodiment using the lateral flow deposition apparatus shown in FIG. 4A and FIG. 4B will be described in detail. First, substrates are loaded onto the substrate holders 420a, 420b, and 420c, as described above. Then, the reactor covers 410a, 410b, 410c and the substrate holders 420a, 420b, 420c are contacted with each other to define enclosed reaction spaces. Then, sub-films having a first intermediate thickness are formed on the substrates by sequentially supplying reactant gases into the reaction chambers. In one example, in which a single film is to be deposited in three stages with intervening rotation between substrate orientations and gas flow directions, the first intermediate thickness may be about ⅓ of a desired final thickness.

Next, the supply of the reactant gases is stopped and the substrate holders 420a, 420b, and 420c are moved downward. The substrate loaded on the substrate holder 420a is transferred to the substrate holder 420b, the substrate loaded on the substrate holder 420b is transferred to the substrate holder 420c, and the substrate loaded on the substrate holder 420c is transferred to the substrate holder 420a by raising, rotating 120°, and lowering the arm axis 492. Here, unlike the deposition apparatus shown in FIG. 3, the substrate holders 420a, 420b, and 420c move vertically, but do not rotate in a horizontal direction. Next, when the substrates are positioned on the next substrate holders, the substrate holders 420a, 420b, and 420c are moved upward to form enclosed reaction spaces. Then, the second sub-films on the substrates are grown to a second intermediate thickness by sequentially supplying reactant gases into the reaction chambers. The second intermediate thickness may be about ⅔ of the desired final thickness, i.e., another sub-film (preferably of the same material) having about ⅓ of the final thickness is deposited during this step.

Next, the supply of the reactant gases is again stopped and the substrate holders 420a, 420b, and 420c are again moved downward. The substrate loaded on the substrate holder 420a is transferred to the substrate holder 420b, the substrate loaded on the substrate holder 420b is transferred to the substrate holder 420c, and the substrate loaded on the substrate holder 420c is transferred to the substrate holder 420a by the arm axis 492. Next, when the substrates are positioned on the next substrate holders, the substrate holders 420a, 420b, and 420c are moved upward to form enclosed reaction spaces. Then, the films on the substrates are grown with another sub-film thickness by sequentially supplying reactant gases (for an ALD example) into the reaction chambers, e.g., another film having about ⅓ of the final thickness is deposited during this step.

After the film having the desired thickness is formed, supply of the reactant gases is stopped and the substrate holders 420a, 420b, and 420c are moved downward. Next, the three substrates are unloaded from the reaction chambers and three new substrates are loaded into the reaction chambers. The above processes can be repeated for other substrates.

As described above, films are deposited while exposing the substrates to different flow directions (relative to the substrate orientation) in different chambers. Accordingly, a film having a uniform thickness may be deposited in the lateral flow deposition apparatus and a plurality of substrates may be processed simultaneously.

Even though the present embodiment is described in a case of three reaction chambers, the deposition apparatus may include two to eight reaction chambers, and preferably includes two to four reaction chambers as described above. The rotation angle of the substrates may be changed by the number of reaction chambers such that the rotation angle of the substrate holders may be about 180°, about 120°, and about 90° when the number of the reaction chambers is two, three, and four, respectively.

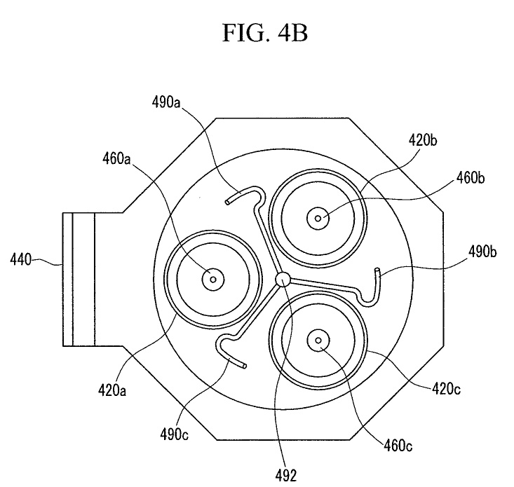

Now, a lateral flow deposition apparatus and a deposition method using the deposition apparatus according to another embodiment will be described with reference to FIG. 5. FIG. 5 is a schematic plan view of a lateral flow deposition chamber having four reaction chambers according to another embodiment.

Referring to FIG. 5, the reactor 500 includes four reaction chambers 520a, 520b, 520c, and 520d. In FIG. 5, the gas flow direction in each reaction chamber is shown by arrows. Now, the deposition method according to one embodiment, using the lateral flow deposition apparatus shown in FIG. 5, will be described.

First, films having a thickness of about ¼ of a desired thickness are formed on substrates under the state in which the substrates are loaded on four reaction chambers 520a, 520b, 520c, and 520d. Then the substrates are transferred to adjacent reaction chambers 520b, 520c, 520d, and 520a, respectively. Assuming that the substrates are rotated from chamber to chamber, the inner edge of the substrate maintains its orientation relative to the center of the reactor 500, but the orientation relative to the gas flow changes. The above processes are repeated four times, each stage depositing about ¼ of the desired film thickness, to deposit a film having the desired thickness. On the other hand, if the desired film thickness is to be achieved in two circuits of the reaction chambers 520a, 520b, 520c, 520d, 8 such repetitions can be conducted, each stage depositing about ⅛ of the desired film thickness. Accordingly, films are deposited while changing the flow direction of reactant gases on the substrates by 90° sequentially by transferring the plurality of substrates from one reaction chamber to another. For ALD reactions, each stage involves multiple cycles.

In another embodiment, a film having a desired thickness may be formed by dividing the desired thickness of the film into two using the deposition apparatus of FIG. 5. Films having a thickness of about ½ of the desired thickness may be formed on substrates while the substrates are loaded in four reaction chambers 520a, 520b, 520c, and 520d. Then, the substrates are transferred to the opposite reaction chambers 520c, 520d, 520a, and 520b respectively, instead of the adjacent reaction chambers 520b, 520c, 520d, and 520a. Additional films having a thickness of about ½ of the desired thickness are formed on the substrates in the opposite reaction chambers.

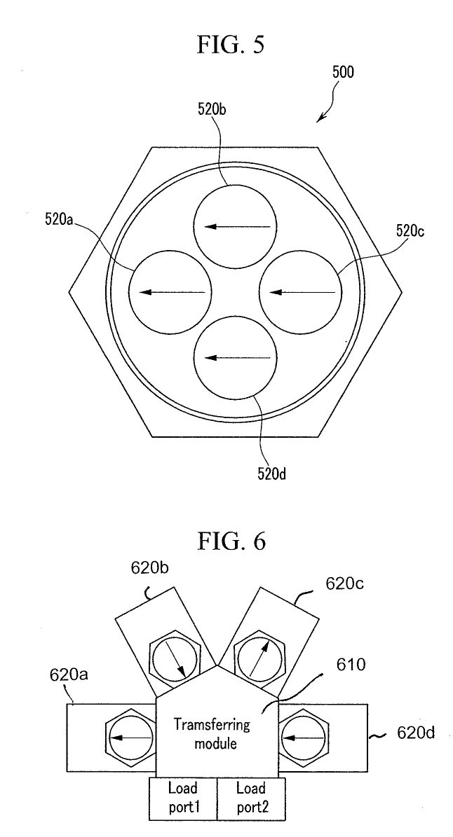

Now, a lateral flow deposition apparatus according to another embodiment will be described with reference to FIG. 6. FIG. 6 is a cross-sectional view of the lateral flow deposition apparatus. The illustrated lateral flow deposition apparatus includes a plurality of independent reaction chambers 620a-620d and a transferring module 610 configured to load, unload, or transfer substrates between the reaction chambers 620a-620d. The transferring module 610 may include a robot arm.

The gas flow on the substrate is maintained substantially lateral, and the gas flow direction in each reaction chamber is shown by arrows in FIG. 6. As shown in FIG. 6, the gas flow directions in the reaction chambers 620a-620d are constant and different from one another, relative to the center of the transfer module. In addition, at least two of the reaction chambers 620a-620d have opposite gas flow directions from each other, relative to the center of the transfer module.

Now, the deposition method according to one embodiment, using the lateral flow deposition apparatus shown in FIG. 6 will be described. Two substrates are loaded on two reaction chambers having the opposite gas flow directions among the reaction chambers 620a-620d using the transferring module 610. Films having a thickness of about ½ of a desired thickness are formed on the substrates. Then, the two substrates are transferred to the other reaction chambers having the opposite gas flow directions by using the transferring module 610. Other films having a thickness of about ½ of the desired thickness are formed on the preformed films on the substrates. Accordingly, films are deposited while changing the flow direction of reactant gases on the substrates by transferring the substrates between the reaction chambers having the opposite gas flow directions, thereby depositing films having a uniform thickness. It will be understood that other portions of the desired film thickness can be selected, and twice as many transfers are needed if ¼ of the deposition is conducted at each stage.

The number of process modules to process in each reaction chamber may depend on the number of gas flow directions in each reaction chamber. Accordingly, if the number of gas flow directions in each reaction chamber is too numerous, too many process modules are used to deposit films. Therefore, it is preferable that the number of process modules is not too many. The lateral flow deposition apparatus shown in FIG. 6 includes only two reaction chambers having opposite gas flow directions per film (620a, 620b for one film and 620c, 620d for another), so efficiency of the deposition apparatus may be improved. In other embodiments, the deposition apparatus may have four reaction chambers per film, depending on plumbing and programming.

In FIG. 6, “opposite” flow patterns are determined relative to a center of the transferring modules. While the mechanism of transfer differs, each of FIGS. 3, 4B, 5, and 6 effectively employ rotational transfer, such that substrate orientations remain fixed relative to a radial direction (relative to the reactor or cluster tool center). In the case of FIG. 6, a wafer handling robot, with an axis of rotation at the center, may load/unload wafers.

As described above, the cluster deposition apparatus having independent process modules instead of a plurality of reaction chambers in one reactor may be applied to the deposition method according to embodiments of the present invention.

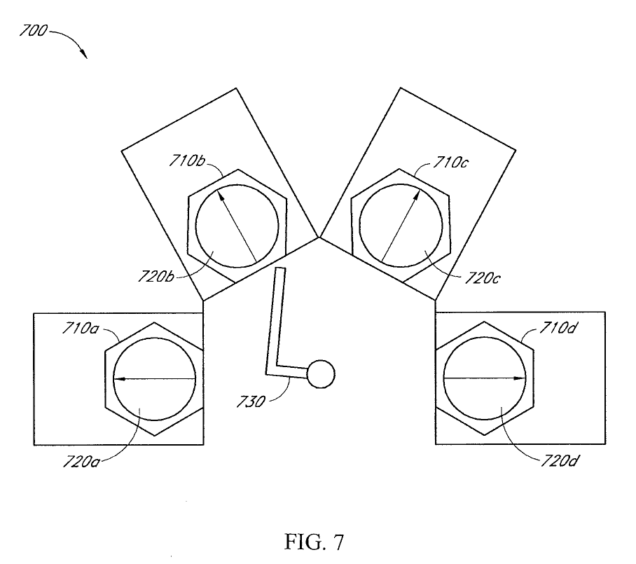

Referring to FIG. 7, another embodiment of deposition apparatus will be described below. The illustrated deposition apparatus 700 includes four reaction chambers 710a-710d and a robot arm 730. Each of the reaction chambers 710a-710d is used to process a single substrate 720a-720d at a time. Each of the reaction chambers 710a-710d is configured to provide a laminar reaction gas flow over the substrate 720a-720d processed therein. The gas flow directions in the reaction chambers 710a-710d are denoted by arrows in the chambers 710a-710d. In the illustrated embodiment, the reaction chambers 710a-710d are arranged to form a substantially half circle, and all the gas flow directions extend radially from the center of the half circle toward the periphery of the half circle, and thus can be considered to have the same gas flow orientations relative to the center of the deposition apparatus 700.

The robot arm 730 is configured to transfer a substrate from one of the reaction chambers 710a-710d to another. When transferring the substrate, the robot arm 730 may rotate the substrate such that the substrate is in different orientations relative to the gas flow directions in different reaction chambers 710a-710d. The robot arm 730 can have a mechanism to rotate a substrate while the substrate is held by the robot arm 730. Alternatively, the robot 730 can work in conjunction with a stand-alone alignment device, which can change the substrate angular orientation relative to the robot 720 and effector, and thus relative to the gas flow directions. As with FIG. 7, the number of chambers may be selected depending on how many deposition circuits are performed to form a film. The fewer the number of deposition circuits is, the better efficient the deposition process is. However, the more the number of deposition circuits is, the more uniformity the resulting film has. Details of a process of forming a film using the apparatus 700 can be as described above with respect to the above embodiments, except for the configurations of the reaction chambers and the use of the robot arm. A skilled artisan will appreciate that the reaction chambers can be arranged any suitable manner, and the robot arm can adjust the orientation of the substrate, depending on the arrangement of the reaction chambers and their gas flow directions.

In the embodiments described above, either the substrate orientation or gas flow direction is changed to provide different relative positions between the substrate orientation and the gas flow direction. In other embodiments, such different relative positions can also be achieved by changing both the substrate orientation and the gas flow direction.

While this invention has been described in connection with what is considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of depositing a film over a substrate, the method comprising in sequence:
flowing one or more reactant gases horizontally over a substrate in a first direction relative to the substrate until a first film having a first thickness is formed over the substrate, the first thickness being thinner than a target thickness;
stopping flowing the reactant gases over the substrate; and
flowing the reactant gases horizontally over the substrate in a second direction relative to the substrate until a second film having a second thickness is formed over the first film, the second thickness being thinner than the target thickness, the second direction being different from the first direction.

2. The method of claim 1, wherein each of the first and second thicknesses is about 1/n of the target thickness, where n is a natural number equal to or greater than 2.

3. The method of claim 2, wherein n is a natural number of 2 to 8.

4. The method of claim 1, wherein the second direction is different in angle from the first direction by about 360°/n, n being a natural number equal to or greater than 2.

5. The method of claim 1, wherein the method comprises maintaining the flow direction of the reactant gases constant, and wherein the method further comprises rotating the substrate while stopping flowing the reactant gases.

6. The method of claim 1, wherein the method comprises maintaining the orientation of the substrate constant, and wherein the method further comprises changing the direction of the reactant gases for flowing the reactant gases in the second direction.

7. The method of claim 1, wherein the method comprises changing the orientation of the substrate and changing the direction of the reactant gases for flowing the reactant gases in the second direction.

8. A method of depositing a film over a substrate, the method comprising in sequence:
flowing one or more reactant gases horizontally over a substrate in a first direction in a first reactor to form a first film over the substrate;
transferring the substrate from the first reactor to a second reactor; and
flowing the same reactant gases horizontally over the substrate in a second direction in the second reactor to form a second film over the first film, the second direction being different from the first direction relative to the substrate, the first and second films being formed of the same material.

9. The method of claim 8, wherein the first film has a first thickness thinner than a target thickness, and wherein the second film has a second thickness thinner than the target thickness.

10. The method of claim 9, wherein each of the first and second thicknesses is about 1/n of the target thickness, where n is a natural number equal to or greater than 2.

11. The method of claim 10, wherein n is a natural number of 2 to 8.

12. The method of claim 8, wherein the second direction is different in angle from the first direction by about 360°/n, n being a natural number equal to or greater than 2.

13. The method of claim 8, wherein the direction of the reactant gases in the first reactor is substantially parallel to the direction of the reactant gases in the second reactor, and wherein transferring the substrate comprises rotating the substrate.

14. The method of claim 8, wherein the direction of the reactant gases in the first reactor is different in angle from the direction of the reactant gases in the second reactor.

15. The method of claim 8, wherein the direction of the reactant gases in the first reactor is different in angle from the direction of the reactant gases in the second reactor, and wherein transferring the substrate comprises rotating the substrate.

16. An apparatus for depositing a thin film over a substrate, the apparatus comprising:
a reaction chamber configured to define an enclosed reaction space in which deposition is performed on a substrate, the reaction space being configured to provide a laminar gas flow in a direction over the substrate; and
a driver configured to rotate the substrate while deposition is not performed on the substrate such that the orientation of the substrate relative to the direction of the laminar gas flow is different from the orientation of the substrate before being rotated.

17. The apparatus of claim 16, wherein the reaction chamber further comprises a reactor cover and a substrate holder together configured to form the reaction chamber, and wherein the reactor cover and the substrate holder are configured to be separated from each other while the driver rotates the substrate.

18. The apparatus of claim 16, further comprising a gas flow control guide structure configured to define the reaction space with the substrate holder.

19. The apparatus of claim 17, further comprising a supporting pin configured to support the substrate while the reactor cover and the substrate are separated from each other, wherein the driver is configured to rotate the supporting pin.

20. The apparatus of claim 16, wherein the driver is configured to rotate the substrate by an angle of about 360°/n at a time, and wherein n is a natural number greater than 2.

21. The apparatus of claim 20, wherein n is a natural number of 2 to 8.

22. An apparatus for depositing a thin film over a substrate, the apparatus comprising:
a plurality of reaction chambers, each of the reaction chambers being configured to define an enclosed reaction space in which deposition is performed on a substrate, the reaction space being configured to provide a laminar gas flow in a direction over the substrate, the reaction chambers being configured to provide the same reactant gases as one another into the reaction spaces; and
a transfer device configured to transfer a substrate from one of the reaction chambers to another of the reaction chambers, wherein the orientation of the substrate relative to the direction of the laminar gas flow in the one reaction chamber is different from the orientation of the substrate relative to the direction of the laminar gas flow in the other reaction chamber.

23. The apparatus of claim 22, wherein the reaction chambers are configured to provide the reactant gases in substantially the same direction as one another, and wherein the transfer device is further configured to rotate the substrate while transferring the substrate from the one reaction chamber to the other reaction chamber.

24. The apparatus of claim 23, wherein each of the reaction chambers further comprises a reactor cover and a substrate holder together configured to form the reaction chamber, and wherein the reactor cover and the substrate holder of each of the reaction chambers are configured to be separated from each other while the transfer device rotates the substrate.

25. The apparatus of claim 24, wherein each of the reaction chambers further comprises a gas flow control guide structure configured to define the reaction space with the substrate holder.

26. The apparatus of claim 24, further comprising a reactor base configured to support the substrate holders of the reaction chambers at least while the reactor cover and the substrate holder of each of the reaction chambers are separated from each other, wherein the transfer device is configured to rotate the reactor base.

27. The apparatus of claim 24, wherein the transfer device comprises one or more arms, each of the arms being configured to support a substrate while the reactor cover and the substrate holder of each of the reaction chambers are separated from each other, and wherein the one or more arms are configured to transfer the substrate from the one reaction chamber to the other reaction chamber.

28. The apparatus of claim 27, wherein the reaction chambers are arranged to form a substantially enclosed path, wherein the apparatus further comprises an arm axis positioned substantially in the center of the path, and coupled to the one or more arms, and wherein the arm axis is configured to rotate the one or more arms.

29. The apparatus of claim 22, wherein at least two of the reaction chambers are configured to provide the reactant gases in different directions from one another.

30. The apparatus of claim 29, wherein the at least two of the reaction chambers are configured to provide the reactant gases in directions that are different in angle by about 360°/n.

31. The apparatus of claim 22, wherein the transfer device is configured to rotate the substrate by an angle of about 360°/n when transferring the substrate from the one reaction chamber to the other reaction chamber, and wherein n is a natural number greater than 2.

32. The apparatus of claim 31, wherein n is a natural number of 2 to 8.

33. The apparatus of claim 22, wherein the transfer device comprises a robot arm configured to rotate the substrate such that the orientation of the substrate relative to the direction of the laminar gas flow in the one reaction chamber is different from the orientation of the substrate relative to the direction of the laminar gas flow in the other reaction chamber.
